(19) United States
(12) Patent Application Publication
(10) Pub. No.: US 2017/0005063 A1
(43) Pub. Date: Jan. 5, 2017

(54) REFLOW APPARATUS

(71) Applicant: Samsung Electronics Co., Ltd., Suwon-si (KR)

(72) Inventors: Tae-gyu KANG, Cheonan-si (KR); Kun-ho SONG, Asan-si (KR); Jung-hun SUNG, Asan-si (KR); Ju-young YU, Cheonan-si (KR)

(21) Appl. No.: 15/080,566

(22) Filed: Mar. 24, 2016

(30) Foreign Application Priority Data
Jul. 2, 2015 (KR) 10-2015-0094936

(51) Int. Cl. H01L 23/00; B23K 3/08; B23K 1/00

(52) U.S. Cl. CPC H01L 24/742; B23K 1/0016; B23K 3/087; H01L 2224/75102; H01L 2224/75651; H01L 2224/75272; H01L 2924/3512

(57) ABSTRACT

A reflow apparatus include a carrier supporting a printed circuit board placed on a side thereof by using a vacuum pressure generated therein, and a processing chamber including a heating chamber and a cooling chamber, wherein the carrier includes at least one adsorption hole, formed in one side of the carrier, a vacuum space connected to the adsorption hole, and a vacuum control unit capable of maintaining or removing a vacuum pressure in the vacuum space by selective opening and closing a path connecting the vacuum space to the outside.

### CROSS-REFERENCE TO RELATED APPLICATION

This application claims the benefit of Korean Patent Application No. 10-2015-0094936, filed on Jul. 2, 2015, in the Korean Intellectual Property Office, the disclosure of which is incorporated herein in its entirety by reference.

### BACKGROUND

The inventive concept relates to a carrier for reflow processing and a reflow apparatus.

Demand for highly integrated printed circuit boards has increased due to the recent trend for miniaturization and multifunctionality of electronic devices. In accordance with this trend, a thin printed circuit board without a core has been used. However, a coreless printed circuit board with a reduced rigidity has problems such a deflection to a high temperature applied thereto during a reflow process, a non-wet defect, and a bump crack.

### SUMMARY

Example embodiments include a carrier for reflow processing to prevent warpage of a printed circuit board.

Example embodiments include a reflow apparatus including a carrier for reflow processing.

According to example embodiments of the inventive concept, there is provided a reflow apparatus including a carrier which may, for a printed circuit board with a semiconductor chip placed on a top side thereof, fix the printed circuit board onto one side thereof by using a vacuum pressure generated therein, and a processing chamber where the carrier is put in and discharged from, and chips are mounted onto the printed circuit board by performing a reflow process. The carrier may include at least one adsorption hole on one side thereof, a vacuum space interconnected to the adsorption hole therein, and a vacuum control unit capable of maintaining or removing the vacuum pressure in the vacuum space by selective opening or closing of a path of the vacuum space to the outside.

In some embodiments, the vacuum control unit may include a vacuum maintaining unit and a vacuum removing unit.

In some embodiments, at least one of the vacuum maintaining unit and the vacuum removing unit may include a vacuum valve.

In some embodiments, a vacuum pump removing a gas of the vacuum space through the vacuum control unit may be further included.

In some embodiments, a conveying unit traversing the processing chamber and conveying the carrier may be further included.

In some embodiments, the carrier may further include a recess region on one side thereof, and the adsorption hole may be inside the recess region.

In some embodiments, an external side surface of the printed circuit board may be in contact with the recess region.

In some embodiments, the vacuum space may include a first vacuum space and a second vacuum space disconnected from the first vacuum space. The vacuum pressure may maintain or remove in the first vacuum space through a first vacuum control unit, and the vacuum pressure may maintain or remove the second vacuum space through a second vacuum control unit.

In some embodiments, an external side surface of the first vacuum space may be surrounded by the second vacuum space.

In some embodiments, a blocking member placed on one side of the carrier with the adsorption hole and blocking a portion of the adsorption hole from the outside may be further included.

In some embodiments, the adsorption hole may include at least two rows of adsorption holes, the rows are in parallel with and spaced apart from each other, and each row may include at least two adsorption holes.

According to example embodiments of the inventive concept, a reflow apparatus is provided including a loading unit supplying a printed circuit board with a connecting pad on one side thereof, a semiconductor chip with a connecting terminal connected to the connecting pad, and a carrier fixing the printed circuit board by using a vacuum pressure generated therein; a reflow handling unit including a processing chamber and mounting the semiconductor chip onto the printed circuit board by performing a reflow process; an unloading unit separating the printed circuit board from the carrier by removing the vacuum pressure of the carrier; and a conveying unit conveying the carrier between the loading unit and the unloading unit, wherein the carrier may include a vacuum control unit maintaining or removing the vacuum pressure generated inside the carrier.

In some embodiments, the conveying unit may include a first conveying unit conveying the carrier from the loading unit to the unloading unit and traversing the processing chamber, and a second conveying unit conveying the carrier from the unloading unit to the loading unit.

In some embodiments, the vacuum control unit may include a vacuum maintaining unit and a vacuum removing unit.

In some embodiments, at least one of the vacuum maintaining unit and the vacuum removing unit may include a vacuum valve.

According to example embodiments of the inventive concept, a carrier for reflow processing to support a printed circuit board may include a vacuum space capable of providing a vacuum pressure to the inside thereof, at least one of adsorption holes connected to the vacuum space on one side of the carrier, and a vacuum control unit being capable of maintaining or removing the vacuum pressure in the vacuum space by selective opening and closing a path of the vacuum space to the outside.

In some embodiments, the vacuum control unit may include a vacuum maintaining unit and a vacuum removing unit, wherein at least one of the vacuum maintaining unit and the vacuum removing unit may include a vacuum valve.

In some embodiments, the vacuum space may include a first vacuum space and a second vacuum space surrounding the first vacuum space, and the vacuum control unit may include a first vacuum control unit either maintaining or removing a vacuum pressure of the first vacuum space and a second control unit either maintaining or removing a vacuum pressure of the second vacuum space.

In some embodiments, the carrier may further include a recess region on one side thereof with the adsorption hole and the adsorption hole may be in the recess region.

In some embodiments, a blocking member placed on one side of the carrier with the adsorption hole and blocking a portion of the adsorption hole from the outside may be further included.

### BRIEF DESCRIPTION OF THE DRAWINGS

Example embodiments of the inventive concept will be more clearly understood from the following detailed description taken in conjunction with the accompanying drawings in which:

FIG. 1 is a cross-sectional view illustrating a reflow apparatus according to an example embodiment of the inventive concept;

FIG. 2 is a partially exploded perspective view illustrating a carrier according to an example embodiments of the inventive concept;

FIG. 3 is a cross-sectional view taken along line A-A′ of FIG. 2 illustrating the carrier according to an example embodiment of the inventive concept;

FIG. 4 is a cross-sectional view taken along line A-A′ of FIG. 2 illustrating the carrier according to an example embodiment of the inventive concept;

FIG. 5 is an enlarged cross-sectional view of a region B in FIG. 3;

FIG. 6 is a perspective view illustrating a carrier according to an example embodiment of the inventive concept;

FIG. 7 is a partially exploded perspective view illustrating a carrier according to an example embodiment of the inventive concept;

FIG. 8 is a cross-sectional view taken along line C-C′ of FIG. 7 illustrating the carrier according to an example embodiment of the inventive concept;

FIG. 9 is a plan view of the carrier illustrated in FIG. 7;

FIG. 10 is a perspective view illustrating a carrier according to an example embodiment of the inventive concept;

FIG. 11 is a block diagram illustrating a reflow apparatus according to an example embodiment of the inventive concept; and

FIG. 12 is a flowchart illustrating a reflow process using a reflow apparatus according to an example embodiment of the inventive concept.

### DETAILED DESCRIPTION OF THE EMBODIMENTS

Hereinafter, the inventive concept will be described more fully with reference to the accompanying drawings, in which example embodiments of the inventive concept are shown. This inventive concept may, however, be embodied in many different forms and should not be construed as limited to the example embodiments set forth herein. Rather, the embodiments are provided so that the disclosure will be thorough and complete, and will fully convey the scope of the inventive concept to one of ordinary skill in the art. Sizes of components in the drawings may be exaggerated for convenience of explanation. In other words, since sizes and thicknesses of components in the drawings are arbitrarily illustrated for convenience of explanation, the following embodiments are not limited thereto.

Throughout the specification, when a portion “includes” an element, another element may be further included, rather than excluding the existence of the other element, unless otherwise described. Also, throughout the specification, “on” refers to a top or bottom of a target, and does not necessarily mean the top of the target based on a direction of gravity.

In the specification, i) the shapes, sizes, ratios, angles, numbers, operations, and the like shown in the accompanying drawings are merely examples and may vary, ii) the drawings are illustrated from the perspective of an observer, and thus directions and locations may vary based on the location of the observer, iii) like reference numerals may denote like elements in different drawings, iv) expressions such as “at least one of”, when preceding a list of elements, modify the entire list of elements and do not modify the individual elements of the list,” v) an expression used in the singular may encompass the expression in the plural, vi) variations in relation to descriptions regarding the numbers, shapes, size comparisons, position relationships when the descriptions are given without the terms “about,” “substantially,” “relatively,” or the like are possible vii) terms such as “after ˜,” “before ˜,” “next,” “and then,” “here,” “following” shall be understood as not limiting chronological positions, viii) in the case where a position relationship between two items is described with the terms “on ˜,” “on the top of ˜,” or the like, one or more items may be interposed therebetween unless the term “directly” is used in the expression, and ix) descriptions shall be understood to include any and all combinations of one or more of the associated listed items when the items are described by using the conjunctive term “˜ or ˜,” “˜ and/or ˜,” or the like, whereas descriptions shall be understood to include independent items only when the items are described by using the term “˜ or one of ˜.”

While such terms as “first,” “second,” etc., may be used to describe various components, such components must not be limited to the above terms. The above terms are used only to distinguish one component from another.

The terms used in the present specification are merely used to describe example embodiments, and are not intended to limit the inventive concept. An expression used in the singular encompasses the expression of the plural, unless it has a clearly different meaning in the context. In the present specification, it is to be understood that the terms such as “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It is not intended to limit the inventive concept of a reflow apparatus and a carrier for the reflow apparatus to particular modes of practice, and it is to be appreciated that all changes, equivalents, and substitutes that do not depart from the spirit and technical scope of the inventive concept are encompassed in the inventive concept.

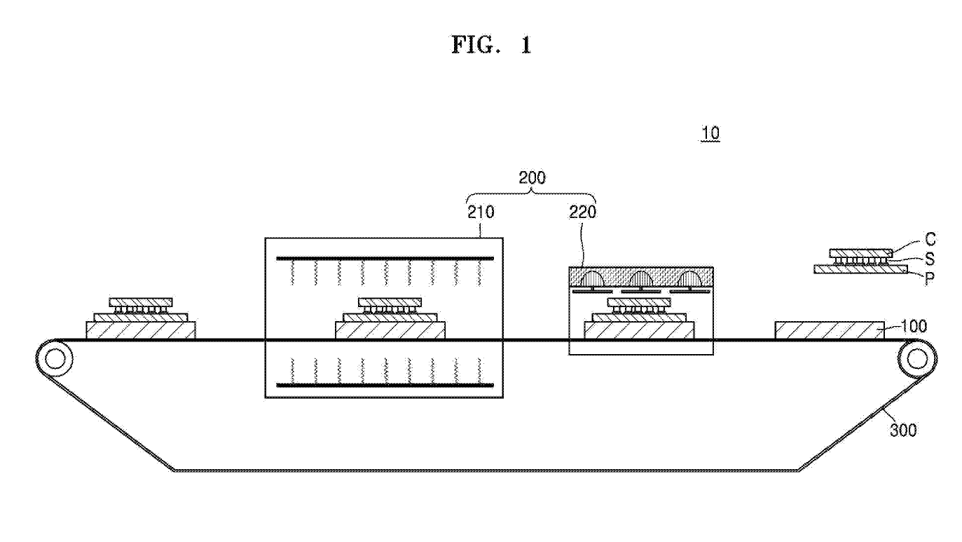

FIG. 1 is a cross-sectional view illustrating a reflow apparatus according to an example embodiment of the inventive concept.

Referring to FIG. 1, the reflow apparatus 10 may include a printed circuit board P with a connecting pad on one side thereof, a semiconductor chip C with a connecting terminal S connected to the connecting pad, a carrier 100 supporting the printed circuit board P by using a vacuum pressure generated therein, a processing chamber 200 including a heating chamber 210 and a cooling chamber 220, and a conveying unit 300 traversing the processing chamber 200.

The carrier 100 may generate the vacuum pressure in a space thereof. The printed circuit board P may be absorbed onto the carrier 100 by providing the vacuum pressure to the top side of the carrier 100 on which the printed circuit board P is provided. The carrier 100 may fix the printed circuit board P in close surface-contact with one side thereof during a transfer, and the printed circuit board P may maintain a state of close surface-contact with one side of the carrier while a reflow process is performed.

The printed circuit board P may include a circuit pattern therein and the connecting pad connecting the circuit pattern and an external connector. The circuit pattern P may be, for example, a coreless plate without a core.

The semiconductor chip C may include a connecting terminal S on a bottom surface thereof and the connecting terminal S may be, for example, a solder bump; however, it is not limited thereto, and various printed circuit boards P and various semiconductor element structures may be used.

The processing chamber 200 may include a heating chamber 210 and a cooling chamber 220, and both the heating chamber 210 and the cooling chamber 220 may have a processing space in which the reflow process is performed.

The heating chamber 210 and the cooling chamber 220 may be spaced apart from each other, and the heating chamber 210 and the cooling chamber 220 may be arranged in sequence in a moving direction of the conveying unit 300. The carrier 100 may be conveyed by the conveying unit 300, and may pass through the heating chamber 210 and the cooling chamber 220 in sequence.

The heating chamber 210 may receive the printed circuit board P and is an area where a heat may be applied to the printed circuit board P. The heating chamber 210 may include an inlet on one side thereof to put in the carrier 100 and an outlet on the other side thereof to discharge the carrier 100, and an exhaust opening to emit a gas therein.

The heating chamber 210 may include a preheating region and a heating region. The preheating region is a section where a temperature lower than a processing temperature in the heating region is maintained for a predetermined time, and may include a heater to supply a heated wind. The processing temperature in the preheating region may be in a range of, for example, about 130° C. to about 170° C.; however, the processing temperature may vary depending on process conditions. The preheating region may prevent a phenomenon that the connecting terminal S flares out. The heating region may melt the connecting terminal S preheated in the preheating region, and mount the semiconductor chip C onto the printed circuit board P. The processing temperature in the heating region may be in a range of, for example, about 170° C. to about 260° C.; however, it may vary depending on processing conditions.

The cooling chamber 220 may be an area where the printed circuit board P discharged from the heating chamber 210 is cooled. The cooling chamber 220 may include an inlet on one side thereof to put in the carrier 100, an outlet on the other side thereof to discharge the carrier 100, and an exhaust opening to emit the gas therein.

The cooling chamber 220 may decrease the temperature of the printed circuit board P to, for example, about 40° C. The cooling chamber 220 may cool down the printed circuit board P so that melted connecting terminal S may get hardened. In the cooling chamber 220, the connecting terminal S may slowly get hardened, and the semiconductor chip C and the printed circuit board P may maintain a stably combined state.

Warpage may occur while the printed circuit board P passes through the processing chamber 200 in a high temperature environment, and a non-wet defect may occur due to the warpage. Thus, the connecting terminal S at a portion of the printed circuit board P may not be normally connected to the connecting pad of the printed circuit board P, which may reduce the reliability of an electronic device.

According to some embodiments, the carrier 100 may be in close contact with the printed circuit board P due to use of the vacuum pressure while passing through the processing chamber 200. Thus, an occurrence of warpage of the printed circuit board P due to the high temperature during the reflow process may be prevented, and also the non-wet defect rate may be significantly reduced. As a result, the reliability of the electronic device may be enhanced.

The printed circuit board P with the semiconductor chip C mounted thereon and the carrier 100 may be separated after the reflow process is performed in the processing chamber 200. The carrier 100 may suck in the outside air to remove the vacuum pressure generated inside the carrier 100, and thus, the printed circuit board P fixed onto the carrier 100 due to a pressure differential may be separated from the carrier 100.

The conveying unit 300 may traverse the inside of the heating chamber 210 and the cooling chamber 220, and may convey the carrier 100. The conveying unit 300 may include, for example, a set of pulleys and a belt wrapped around the set of pulleys, or may include a chain-type conveyer. The conveying unit 300 may include a caterpillar.

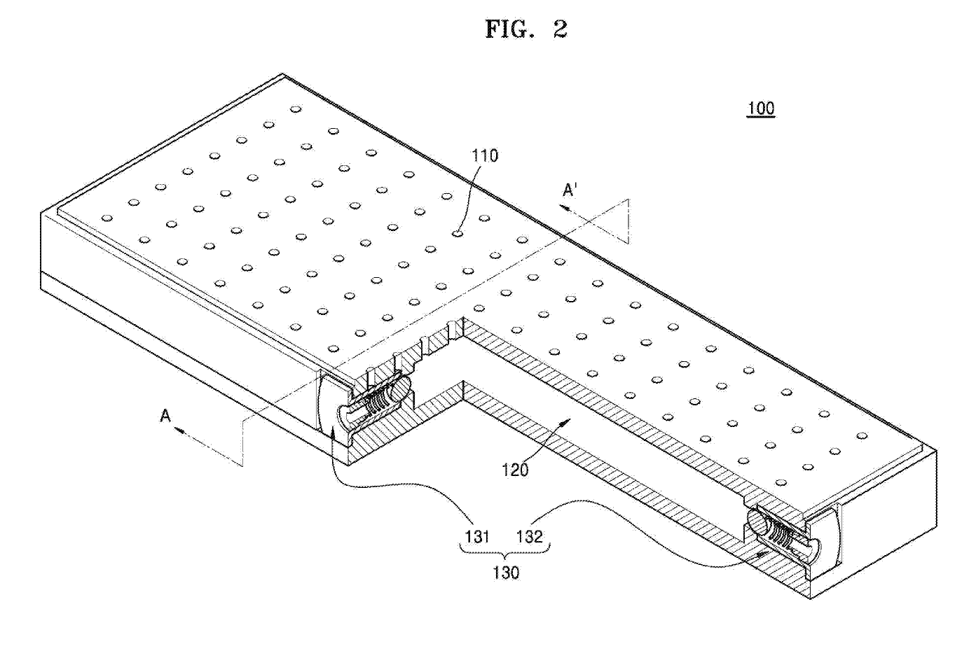

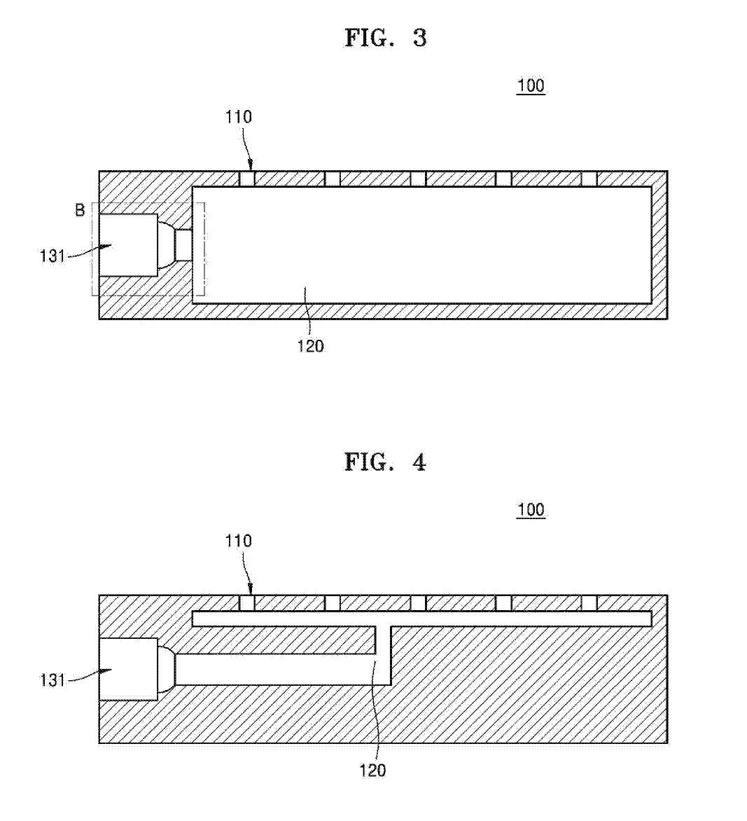

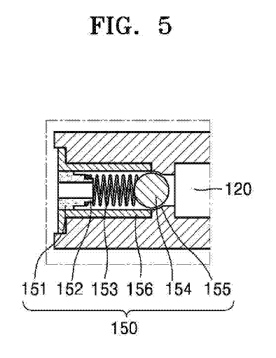

FIG. 2 is a partially exploded perspective view illustrating a carrier 100 according to an example embodiment of the inventive concept. FIG. 3 is a cross-sectional view taken along line A-A′ of FIG. 2 illustrating the carrier 100 according to an example embodiment of the inventive concept. FIG. 4 is a cross-sectional view taken along line A-A′ in FIG. 2 illustrating the carrier 100 according to an example embodiment of the inventive concept; and FIG. 5 is an enlarged cross-sectional view of a region B in FIG. 3.

Referring to FIG. 2, an adsorption hole 110 may be formed in one side of the carrier 100. The adsorption hole 100 may be formed in plurality. The adsorption hole 110 may pass through one side of the carrier 100 in a direction perpendicular to a base surface of the carrier 100, and may be connected to a vacuum space 120 to be described below.

When a plurality of adsorption holes 110 are formed, the adsorption holes 110 may be formed in at least two rows in parallel with each other, and each row may include at least two adsorption holes 110. The rows may be spaced apart from each other by same gap, and at least two adsorption holes 110 included on each row may be spaced apart from each other by the same gap. A force applied onto a bottom surface of the printed circuit board P through the plurality of adsorption holes 110 may be equally distributed, by arranging locations of the plurality of adsorption holes 110 equally spaced apart each other as described above.

In addition, the plurality of adsorption holes 110 may be totally covered by the printed circuit board P in order to prevent the outside air from flowing into the inside of the carrier 100 with the vacuum pressure generated therein. Accordingly, a number and an arrangement shape of the adsorption hole 110 may be changed by considering a size of the printed circuit board P used in the process.

Referring to FIGS. 2 and 3, a vacuum control unit 130 may be placed on one side of the carrier 100. The vacuum control unit 130 may selectively open and close a path between the vacuum space 120 and the outside, and thus, may maintain or remove the vacuum pressure generated inside the carrier 100. The vacuum control unit 130 may include, for example, a vacuum valve.

The vacuum control unit 130 may maintain the vacuum pressure generated in the vacuum space 120 by blocking an outside air from the vacuum space 120 while the reflow process is performed with the carrier passing through the processing chamber 200. In addition, the vacuum control unit 130 may remove the vacuum pressure by connecting the outside air to the vacuum space 120 and allowing the outside air to flow into the carrier 100 discharged from the processing chamber 200, after the reflow process is performed. According to some embodiments, the carrier 100 may independently maintain or remove the vacuum pressure by using the vacuum control unit 130 and thus, may not need a separate vacuum supply pipe while the reflow process is performed. Thus, the carrier 100 may freely move and the reflow apparatus may automatically go through cycles.

The vacuum control unit 130 may include a vacuum maintaining unit 131 and a vacuum removing unit 132. The vacuum maintaining unit 131 may be configured to maintain the vacuum pressure while the carrier 100 passes through the processing chamber 200 where the reflow process is performed, and the vacuum removing unit 132 may be configured to remove the vacuum pressure to separate the printed circuit board P from the carrier 100 passed through the processing chamber 200.

The vacuum space 120 may be formed in the carrier 100 and be defined as an internal region of an inner wall of the carrier 100. The vacuum space 120 may provide a space where the vacuum pressure is generated inside the carrier 100. The vacuum space 120 may have a single conformal void shape formed inside the inner wall. The vacuum space 120 may be connected to the adsorption hole 110 passing through one side of the carrier 100, and in addition, to the vacuum maintaining unit 131 and the vacuum removing unit 132 placed on one side of the carrier 100.

Referring to FIGS. 2 and 4, the vacuum space 120 may include a void portion and a pipe portion connected from the vacuum control unit 130. The void portion may be close to an area where the adsorption holes 110 are formed and may be connected to all of the adsorption holes 110. The pipe portion may be extended from the vacuum maintaining unit 131 and connected to the void portion, and in addition, may be extended from the vacuum removing unit 132 and connected to the void portion.

Referring to FIGS. 2, 3 and 5, the vacuum maintaining unit 131 and the vacuum removing unit 132 may include a vacuum valve 150 including a body member 151, an elastic member 153, a ball 154 and a frame 156.

The body member 151 may be inside the frame 156 and move in an axial direction. The body member 151 may be connected to one end of the elastic member 153, and may include a projection portion 152 at a portion connected to the elastic member 153. An outside diameter of the projection 152 may be less than that of the elastic member 153, and the elastic member 153 may surround an outer circumferential surface of the projection portion 152.

The elastic member 153 may be placed between the ball 154 and the body member 151, and may include an elastic material such as a spring and an elastic rubber.

The vacuum valve 150 may remain in a closed state according to the following method. The body member 151 may move in the axial direction to compress and provide an elastic force to the elastic member 153. Then, the elastic member 153 may exert an external force onto the ball 154 to be caught at a catching protrusion 155 and be fixed. The ball 154 fixed at the catching protrusion 155 may close a path between the vacuum space 120 and the vacuum maintaining unit 131. Through a series of such processes, the vacuum valve 150 may prevent an inflow of the outside air into the vacuum space 120, and in addition, may maintain the vacuum pressure generated inside the vacuum space 120 by maintaining the closed state while the reflow process is performed. The vacuum valve 150 may further include a stopper to fix the body member 151 at a particular location, and the body member 151 may maintain the particular location at which the closed state may be maintained by the stopper; however, the vacuum maintaining unit 131 is not limited to a valve operating in such a mechanism according to some embodiments, and various kinds of valves capable of selectively controlling an open/closed state may be included.

In addition, the vacuum removing unit 132 may be configured to selectively open and close a connection between the vacuum space 120 and the outside, and may include the vacuum valve 150 according to some embodiments. When removing the vacuum pressure from the vacuum space 120 by using the vacuum valve 150, the body member 151 may move for the elastic member 153 to relax so that the ball 154 may be separated from the catching protrusion 155 and accordingly, the outside air may flow into the vacuum space 120; however, the vacuum removing unit 132 is not limited to the valve operating in such a mechanism according to some embodiments, and various kinds of valves capable of selectively controlling the open/closed state may be included.

The carrier 100 may be connected to a vacuum pump to supply the vacuum pressure into the carrier 100. The vacuum pump may remove the gas inside the vacuum space 120 through at least one of the vacuum maintaining unit 131 and the vacuum removing unit 132. In addition, the vacuum pump may remove the gas inside the vacuum space 120 through a separate path in the carrier 100.

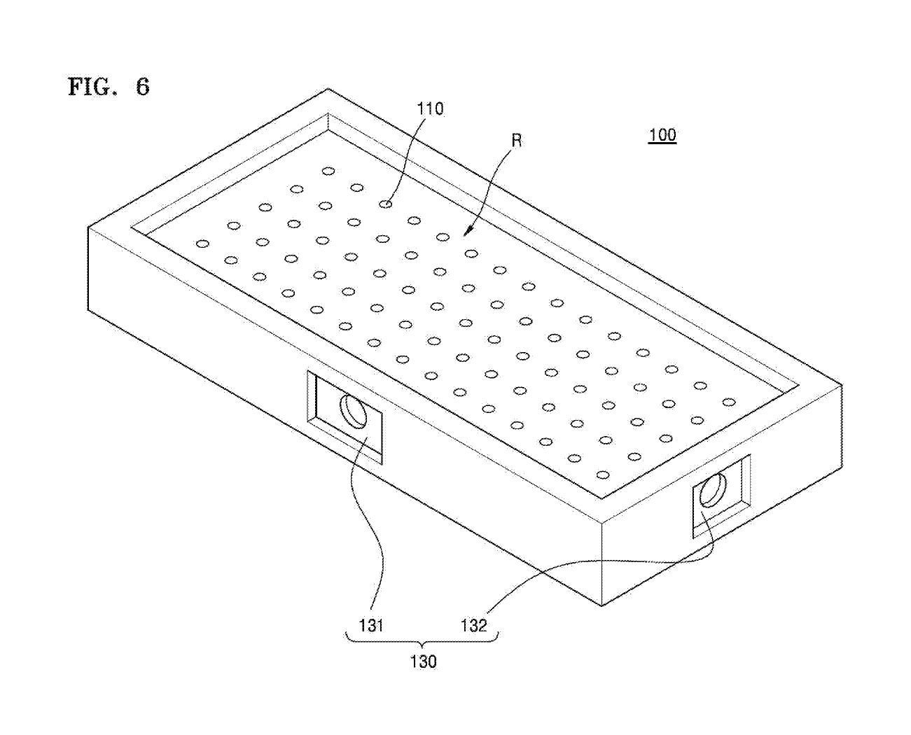

FIG. 6 is a perspective view illustrating a carrier according to an example embodiment of the inventive concept.

Referring to FIG. 6, the carrier 100 may include a recess region R on one side thereof where the printed circuit board P is placed, and the adsorption hole 110 may be inside the recess region R. The printed circuit board P may be inside the recess region R, and the recess region R may be in contact with or spaced apart at a predetermined gap from a side surface of the printed circuit board P. The printed circuit board P may be supported by a side wall formed by the recess region R and be prevented from being shaken in a horizontal direction. In other words, the printed circuit board P may receive a force applied to the printed circuit board P in a vertical direction through the adsorption hole 110 and at the same time, a movement in a horizontal direction thereof may be limited by the recess region R; thus, the printed circuit board P may be prevented from moving away from a predetermined location. A width, a length and a depth of the recess region R may vary depending on kinds of the printed circuit board P used for the process.

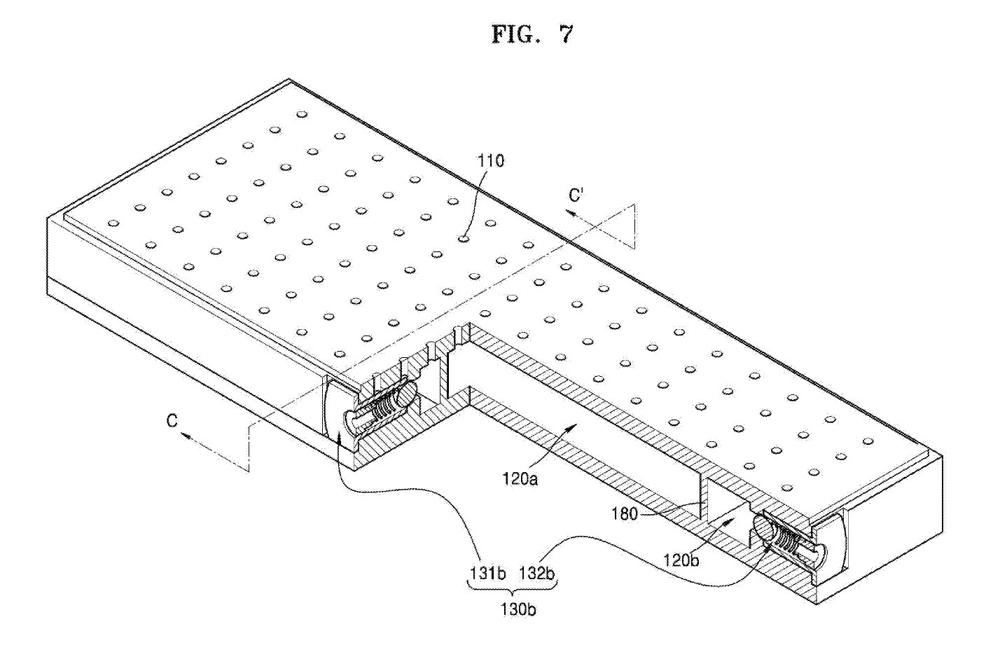

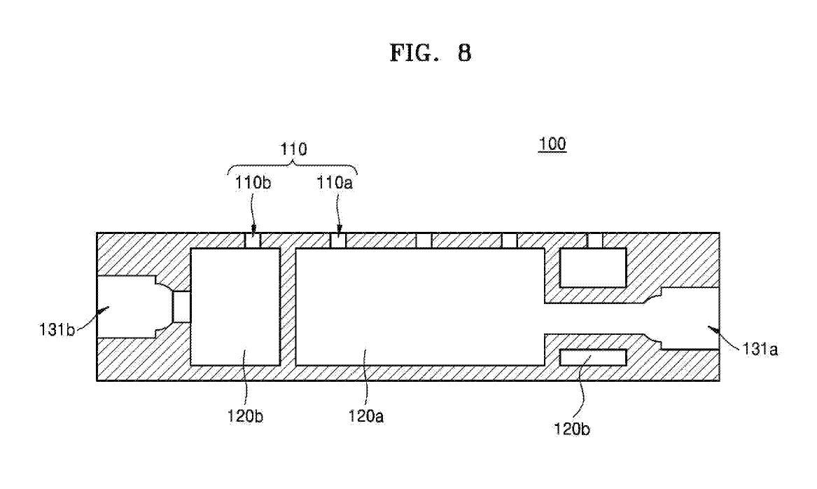

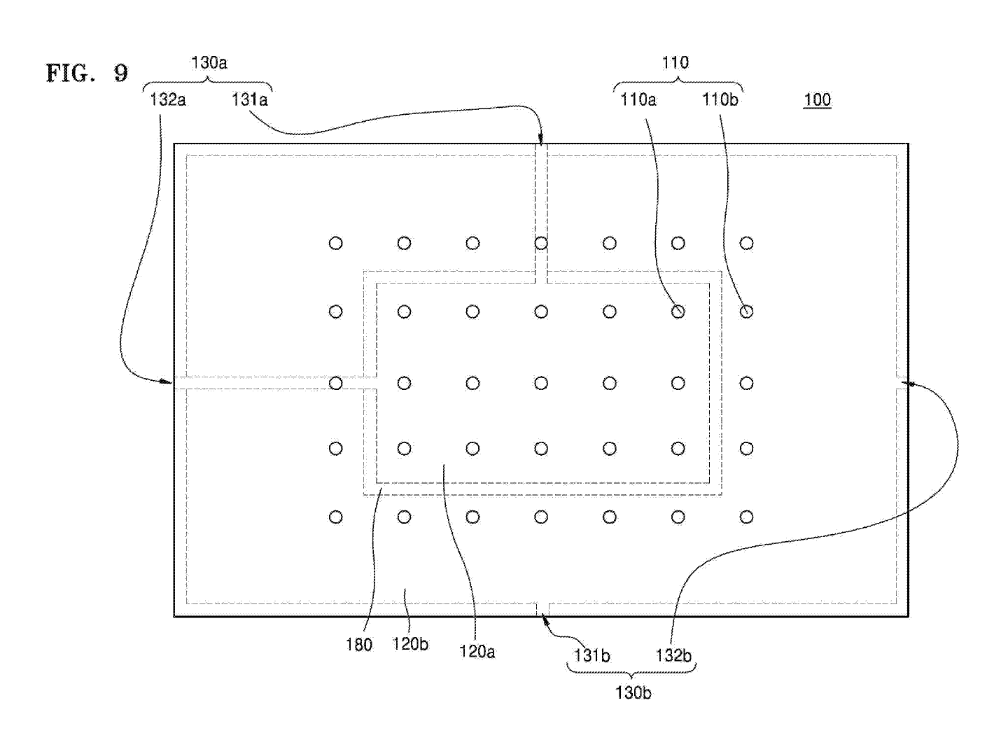

FIG. 7 is a partially exploded perspective view illustrating a carrier according to an example embodiment of the inventive concept. FIG. 8 is a cross-sectional view taken along line C-C′ of FIG. 7 illustrating the carrier according to an example embodiment of the inventive concept. FIG. 9 is a plan view of the carrier illustrated in FIG. 7.

Referring to FIGS. 7 through 9, the carrier 100 may include a first vacuum space 120A and a second vacuum space 120B. The first vacuum space 120A and the second vacuum space 120B may be spaced apart from each other by an inner wall 180 inside the carrier 100.

The first vacuum space 120A may be connected to a first adsorption hole 110A and may selectively maintain or remove the vacuum pressure by a first vacuum control unit 130A placed on one side of the carrier 100. The first vacuum control unit 130A may include a first vacuum maintaining unit 131A and a first vacuum removing unit 132A. Alternatively, a plurality of first adsorption holes 110A may be formed in at least two rows, each of which includes at least two adsorption holes 110A, in parallel with and spaced apart from each other.

The second vacuum space 120B may be connected to a second adsorption hole 110B, and may selectively maintain or remove the vacuum pressure by a second vacuum control unit 130B placed on one side of the carrier 100. The second vacuum control unit 130B may include a second vacuum maintaining unit 131B and a second vacuum removing unit 132B. The second adsorption hole 110B may be in a plurality and the plurality of the second adsorption holes 110B may be formed in at least two rows, each of which includes at least two adsorption holes 110B, arranged in parallel with and spaced apart from each other.

Depending on the size of the printed circuit board P used for the process, the vacuum pressure may be simultaneously generated in both of the first vacuum space 120A and the second vacuum space 120B, or be generated only in one of the first vacuum space 120A and the second vacuum space 120B.

When the printed circuit board P used for the process may cover only a portion of the plurality of the adsorption hole 110, the printed circuit board P may be supported by the vacuum pressure generated in only one of the first vacuum space 120A and the second vacuum space 120B, depending on the size of the printed circuit board P. When the vacuum pressure may be generated in the first vacuum space 120A only, the adsorption force may be applied through the first adsorption hole 110A only. On the other hand, when the vacuum pressure may be generated in the second vacuum space 120B only, the adsorption force may be applied through the second adsorption hole 110B only. Thus, when the printed circuit board P may not cover all of adsorption holes 110, the printed circuit board P may be fixed by generating the vacuum pressure in only one of the first vacuum space 120A and the second vacuum space 120B, and at the same time, an in-flow of the outside air through the adsorption hole 110, uncovered by the printed circuit board P and exposed to the outside, may be prevented.

In addition, when the size of the printed circuit board P may cover all of the first adsorption hole 110A connected to the first vacuum space 120A and the second adsorption hole 110B connected to the second vacuum space 120B, the printed circuit board P may be supported by generating the vacuum pressure in both the first vacuum space 120A and the vacuum space 120B.

Referring to FIGS. 8 and 9, an external side surface of the first vacuum space 120A may be surrounded by the second vacuum space 120B.

When the printed circuit board P may cover only a portion of one side of the carrier 100, the printed circuit board P may be supported by using an adsorption force applied through the first adsorption hole 110A due to the vacuum pressure generated in the first vacuum space 120A; in this case, the vacuum pressure may not be generated in the second vacuum space 120B surrounding the external side surface of the first vacuum space 120A.

In addition, when the printed circuit board P may cover all of the plurality of adsorption holes 110 on one side of the carrier 100, the vacuum pressure may be generated in the second vacuum space 120B, and accordingly, the printed circuit board P may be fixed by the adsorption force applied through the second adsorption hole 110B; in this case, the vacuum pressure may not be generated in the first vacuum space 120A surrounded by the second vacuum space 120B. The printed circuit board P may be fixed onto one side of the carrier 100 since the adsorption force may be applied through the second adsorption hole 110B onto a peripheral area of the bottom side of the printed circuit board P. Thus, warpage of the peripheral area of the printed circuit board P may not occur even when a high temperature is applied to the printed circuit board P.

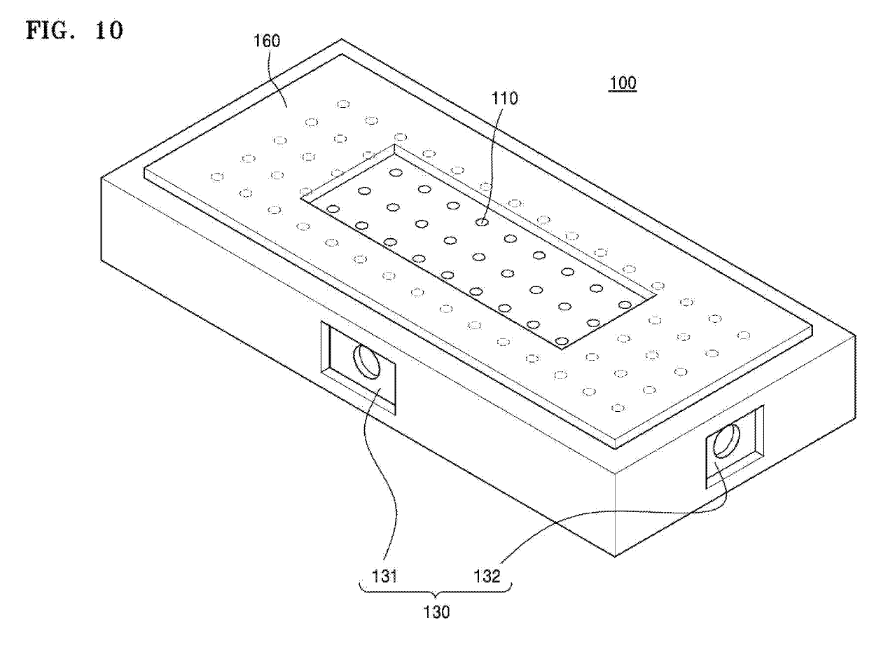

FIG. 10 is a perspective view illustrating a carrier according to an example embodiment of the inventive concept.

Referring to FIG. 10 with FIG. 2, a blocking member 160 may be on one side of the carrier 100 and may cover a remaining portion of one side of the carrier 100 excluding a portion where the printed circuit board P may be placed. The blocking member 160 may block the adsorption hole 100 exposed to the outside due to not being covered by the printed circuit board P and may prevent the vacuum pressure from being removed by an in-flow of the outside air. The blocking member 160, like the printed circuit board P, may be in close contact with the carrier 100 by using the pressure differential between the vacuum pressure inside the carrier 100 and an outside pressure during a conveying process of the carrier 100, or may be fixed onto one side of the carrier 100 by using a mechanical fastening device.

The blocking member 160 may have a plate shape with a hollow central portion. The printed circuit board P may have the side surface in contact with the hollow central portion of the blocking member 160. In other words, the external side surface of the printed circuit board P may be surrounded by the blocking member 160. Since the blocking member 160 surrounds the external side surface of the printed circuit board P even when the carrier 100 is shaken, the blocking member 160 may prevent the printed circuit board P from being shaken in the horizontal direction; accordingly, the blocking member 160 may stably fix the printed circuit board P together with the adsorption force applied in the vertical direction through the adsorption hole 110.

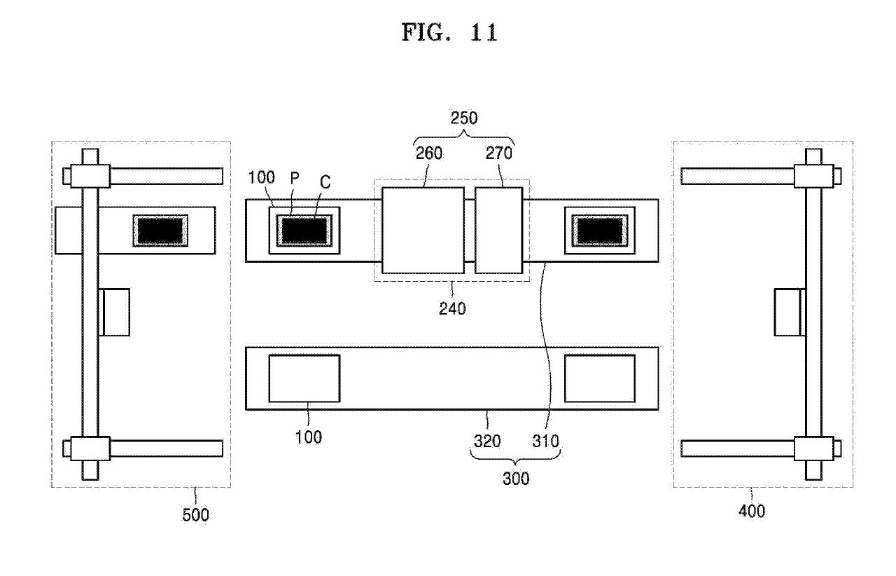

FIG. 11 is a block diagram illustrating a reflow apparatus according to an example embodiment of the inventive concept.

Referring to FIG. 11, the reflow apparatus 10 may include a loading unit 500, a reflow handling unit 240, the conveying unit 300 including a first conveying unit 310 and a second conveying unit 320, and an unloading unit 400.

The loading unit 500 may receive the carrier 100 from the second conveying unit 320, and the printed circuit board P having the semiconductor chip C on one side thereof. After the printed circuit board P is placed on one side of the carrier 100, the printed circuit board P may be fixed onto the carrier 100 by generating the vacuum pressure until the printed circuit board P may be sufficiently in close contact with the inside of the carrier 100. The loading unit 500 may include a vacuum pump to generate the vacuum pressure inside the carrier 100 by removing the gas inside the carrier 100, and the vacuum pump may remove the gas inside the carrier 100 through the vacuum control unit 130 illustrated in FIG. 2, which is placed on one side of the carrier 100.

The reflow handling unit 240 may perform the reflow process and include the processing chamber 250 providing a handling space for the reflow process to be performed. The processing chamber 250 may include the heating chamber 260 and the cooling chamber 270. The heating chamber 260 may melt the connecting terminal S and the cooling chamber 270 may cool the printed circuit board P so that the connecting terminal S melted may be hardened. Thus, the semiconductor chip C may be mounted onto the printed circuit board P through a series of such processes.

The unloading unit 400 may receive the carrier 100 from the first conveying unit 310. The printed circuit board P with the semiconductor chip C mounted thereon may be separated from the carrier 100 by removing the vacuum pressure inside the carrier 100. In this case, the carrier 100 may open a vacuum removing valve, allow the outside air to flow into the carrier 100, and thus, remove the vacuum pressure. The carrier 100 separated from the printed circuit board P may be transferred to the second conveying unit 320.

The conveying unit 300 may include the first conveying unit 310 transferring the carrier 100 from the loading unit 500 to the unloading unit 400 and traversing the reflow handling unit 240, and the second conveying unit 320 transferring the carrier 100 from the unloading unit 400 to the loading unit 500.

While the carrier 100 supporting the printed circuit board P on one side thereof passes through the reflow handling unit 240 along the first conveying unit 310, the reflow process may be performed such that the semiconductor chip C may be mounted onto the printed circuit board P. The first conveying unit 310 may include, for example, a set of pulleys and a set of belts wrapped around pulleys, and may be a caterpillar. The first conveying unit 310 may simultaneously transfer a plurality of carriers 100. The reflow process is performed while the carrier 100 may pass through the reflow process handling unit 240 by the first conveying unit 310, and a speed of the first conveying unit 310 may be determined by a process to be performed.

The second conveying unit 320 may receive the carrier 100 from the unloading unit 400 and transfer the carrier 100 to the loading unit 500. The second conveying unit 320 may include, for example, a set of pulleys and a set of belts wrapped around pulleys, and may be a caterpillar. The second conveying unit 320, like the first conveying unit 310, may simultaneously transfer a plurality of carriers 100.

According to some embodiments, the carrier 100 may independently maintain or remove the vacuum pressure generated therein and may not need a separate vacuum supply pipe. Thus, the carrier 100 may automatically operate during operation cycles of the first conveying unit 310, the reflow handling unit 240, the unloading unit 400, the second conveying unit 320, and the loading unit 500.

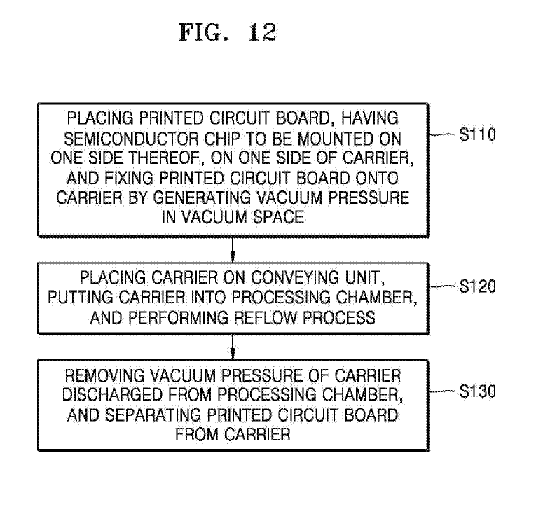

FIG. 12 is a flowchart illustrating a reflow process using a reflow apparatus according to an example embodiment of the inventive concept.

Referring to FIG. 12 with FIGS. 1 through 5, at block S110, the printed circuit board P may be placed on one side of the carrier 100. The printed circuit board P may include a multiplicity of circuit patterns therein, and the connecting pad electrically connected to circuit patterns and exposed to the outside. The semiconductor chip C may include the connecting terminal S on a bottom side thereof and the connecting terminal S may be connected to the connecting pad. The vacuum pump may be connected to the vacuum control unit 130 placed on one side of the carrier 100 or through a separate path in the carrier 100 in order to generate the vacuum pressure inside the carrier 100; and the gas inside the vacuum space 120 may be removed. Since the vacuum control unit 130, which is capable of maintaining or removing the vacuum pressure independently, may be placed on one side of the carrier 100, the carrier 100 may independently maintain the vacuum pressure, and the printed circuit board P may be fixed onto the carrier 100 by the pressure differential between the outside pressure and a pressure inside the carrier 100.

At block S120, the carrier 100 with the printed circuit board P fixed thereon may be placed on the belt, and the belt may convey the carrier 100 toward the processing chamber 200. While the carrier 100 may pass through the heating chamber 210 and the cooling chamber 220, the reflow process is performed to the connecting terminal S, and the connecting terminal S may be connected to the connecting pad with a sufficient strength. While the reflow process is performed, the vacuum control unit 130 may maintain the vacuum pressure inside the carrier 100, and the printed circuit board P may maintain a state of close contact with the carrier 100. Thus, the warpage occurring on the printed circuit board P may be prevented even at a high temperature condition.

At block S130, the carrier 100 may be discharged from the processing chamber 200 and the vacuum control unit 130 may remove the vacuum pressure inside the carrier 100 to separate the printed circuit board P from the carrier 100. In this case, the vacuum control unit 130 may connect the outside to the vacuum space 120, allow an in-flow of the outside air into the vacuum space 120, and remove the vacuum pressure inside the carrier 100.

According to some embodiments, the reflow apparatus 10 described above may allow the printed circuit board P to maintain a state of close contact with the carrier 100 while the reflow process is performed. Accordingly, an occurrence of the warpage and the non-wet defect on the printed circuit board P may be prevented. In addition, a vacuum state may be maintained or removed by using a valve, etc., and a separate vacuum supply pipe may not be needed; thus, the carrier 100 may more freely move, an automatic cycling may be feasible, productivity may be enhanced, and a processing cost may be reduced.

While the inventive concept has been particularly shown and described with reference to example embodiments thereof, it will be understood by those of ordinary skill in the art that various changes in form and details may be made therein without departing from the spirit and scope of the following claims.

What is claimed is:

1. A reflow apparatus comprising:
a carrier for a printed circuit board having a semiconductor chip on a top side thereof, the carrier fixing the printed circuit board on a side thereof via a vacuum pressure generated therein; and
a processing chamber where the carrier is placed in and discharged from, and wherein a reflow process is performed to mount the semiconductor chip on the printed circuit board,
wherein the carrier includes at least one adsorption hole in a side thereof, a vacuum space connected to the adsorption hole, and a vacuum control unit capable of maintaining or removing the vacuum pressure in the vacuum space by selective opening and closing a path connecting the vacuum space to the outside.

2. The reflow apparatus of claim 1, wherein the vacuum control unit comprises a vacuum maintaining unit and a vacuum removing unit.

3. The reflow apparatus of claim 2, wherein at least one of the vacuum maintaining unit and the vacuum removing unit comprises a vacuum valve.

4. The reflow apparatus of claim 1, further comprising a vacuum pump to remove a gas from the vacuum space through the vacuum control unit.

5. The reflow apparatus of claim 1, further comprising a conveying unit traversing the processing chamber and conveying the carrier.

6. The reflow apparatus of claim 1, wherein the carrier further comprises a recess region on one side thereof and the adsorption hole is placed inside the recess region.

7. The reflow apparatus of claim 6, wherein an external side surface of the printed circuit board is in contact with the recess region.

8. The reflow apparatus of claim 1, wherein the vacuum space comprises a first vacuum space and a second vacuum space spaced apart from the first vacuum space, and the vacuum pressure maintains or removes in the first vacuum space through a first vacuum control unit and the vacuum pressure maintains or removes in the second vacuum space through a second vacuum control unit.

9. The reflow apparatus of claim 8, wherein an external side surface of the first vacuum space is surrounded by the second vacuum space.

10. The reflow apparatus of claim 1, further comprising a blocking member placed on one side of the carrier with the adsorption hole and blocking a portion of the adsorption hole from the outside.

11. The reflow apparatus of claim 1, wherein the adsorption hole comprises at least two rows of adsorption holes, the rows being in parallel with and spaced apart from each other, and each of the rows comprises at least two adsorption holes.

12. A reflow apparatus comprising:
a loading unit supplying a printed circuit board having a connecting pad on a side thereof, a semiconductor chip having a connecting terminal connected to the connecting pad, and a carrier fixing the printed circuit board via a vacuum pressure generated therein;
a reflow handling unit comprising a processing chamber and mounting the semiconductor chip onto the printed circuit board via a reflow process;
an unloading unit separating the carrier from the printed circuit board by removing the vacuum pressure of the carrier; and
a conveying unit conveying the carrier between the loading unit and the unloading unit,
wherein the carrier comprises a vacuum control unit maintaining or removing the vacuum pressure generated inside the carrier.

13. The reflow apparatus of claim 12, wherein the conveying unit comprises a first conveying unit conveying the carrier from the loading unit to the unloading unit and traversing the processing chamber, and a second conveying unit conveying the carrier from the unloading unit to the loading unit.

14. The reflow apparatus of claim 12, wherein the vacuum control unit comprises a vacuum maintaining unit and a vacuum removing unit.

15. The reflow apparatus of claim 14, wherein at least one of the vacuum maintaining unit and the vacuum removing unit comprises a vacuum valve.

16. A carrier for reflow processing to support a printed circuit board, comprising:
a vacuum space capable of providing a vacuum pressure to the inside thereof;
at least one of adsorption holes connected to the vacuum space on one side of the carrier; and
a vacuum control unit being capable of maintaining or removing the vacuum pressure in the vacuum space by selective opening and closing a path of the vacuum space to the outside.

17. The carrier for reflow processing of claim 16, wherein the vacuum control unit includes a vacuum maintaining unit and a vacuum removing unit, and at least one of the vacuum maintaining unit and the vacuum removing unit includes a vacuum valve.

18. The carrier for reflow processing of claim 16, wherein the vacuum space includes a first vacuum space and a second vacuum space surrounding the first vacuum space, and the vacuum control unit includes a first vacuum control unit either maintaining or removing a vacuum pressure of the first vacuum space and a second vacuum control unit either maintaining or removing a vacuum pressure of the second vacuum space.

19. The carrier for reflow processing of claim 16, further comprising a recess region on one side of the carrier with the adsorption hole,
wherein the adsorption hole is in the recess region.

20. The carrier for reflow processing of claim 16, further comprising a blocking member on one side of the carrier with the adsorption hole, the blocking member blocking a portion of the adsorption hole from the outside.
